(19) United States
(12) Patent Application Publication
(10) Pub. No.: US 2013/0286616 A1
(43) Pub. Date: Oct. 31, 2013

(54) CIRCUIT DEVICE

(71) Applicants: Takashi Shibasaki, Oura-gun (JP); Hidefumi Saito, Isesaki-City (JP); Takahisa Makino, Kiryu-City (JP); Masanori Shimizu, Ashikaga-shi (JP); Daisuke Sasaki, Ota-shi (JP)

(72) Inventors: Takashi Shibasaki, Oura-gun (JP); Hidefumi Saito, Isesaki-City (JP); Takahisa Makino, Kiryu-City (JP); Masanori Shimizu, Ashikaga-shi (JP); Daisuke Sasaki, Ota-shi (JP)

(73) Assignee: ON Semiconductor Trading, Ltd., Hamilton (BE)

(21) Appl. No.: 13/878,724

(22) PCT Filed: Sep. 15, 2011
(86) PCT No.: PCT/JP2011/005211

§ 371 Date: May 22, 2013

(30) Foreign Application Priority Data
Sep. 24, 2010 (JP) 2010-213696

(51) Int. Cl. H05K 1/18

(52) U.S. Cl. CPC H05K 1/18
USPC 361/771; 174/255

(57) ABSTRACT

A circuit device having superior voltage resistance is provided. A structure is achieved that omits the resin layer that is normally provided to the top surface of a circuit board. Specifically, a ceramic substrate (22) is disposed on the top surface of a circuit board (12) comprising a metal, and a transistor (34) such as an IGBT is mounted to the top surface of the ceramic substrate (22). As a result, the transistor (34) and the circuit board (12) are insulated from each other by the ceramic substrate (22). The ceramic substrate (22), which comprises an inorganic material, has an extremely high voltage resistance compared to the conventionally used insulating layer comprising resin, and so even if a high voltage on the order of 1000V is applied to the transistor (34), short circuiting between the transistor (34) and the circuit board (12) is prevented.

### REFERENCE TO RELATED APPLICATIONS

This application is a national stage application under 35 USC 371 of International Application No. PCT/JP2011/005211, filed Sep. 15, 2011, which claims the priority of Japanese Patent Application No. 2010-213696, filed Sep. 24, 2010, the entire contents of which are incorporated herein by reference.

### FIELD OF THE INVENTION

A preferred embodiment of the invention relates to a circuit device, and specifically, relates to a circuit device in which a power semiconductor element for switching a high current is mounted on the upper surface of a circuit board.

### BACKGROUND OF THE INVENTION

With reference to FIG. 8, the configuration of a conventional configuration integrated circuit device 100 will be explained. Firstly, a predetermined electric circuit is formed such that a conductive pattern 103 is formed on the surface of a rectangular substrate 101 with an insulating layer 102 interposed therebetween, and circuit elements are fixed to the conductive pattern 103. Here, as the circuit elements, a semiconductor element 105A is fixed thereto. Further, an electrode formed on an upper surface of the semiconductor element 105A is connected to the desired conductive pattern 103 through a fine metal wire 114. Moreover, a lead 104 is connected to a pad 109 made of the conductive pattern 103 formed in a periphery part of the substrate 101, and functions as an external terminal. A sealing resin 108 has a function of sealing the electric circuit formed on the surface of the substrate 101.

A case material 111 has a frame-like shape, and abuts on the side surfaces of the substrate 101, whereby a space for filling the sealing resin 108 is formed on the upper surface of the substrate 101.

A manufacturing method of the hybrid integrated circuit device 100 of the configuration mentioned above is as follows. Firstly, the conductive pattern 103 having a predetermined shape is formed on the upper surface of the substrate 101, the upper surface coated with the insulating layer 102 made of a resin. Next, a circuit element such as the semiconductor element 105A is placed on the upper surface of the substrate 101, and the predetermined conductive pattern 103 and the semiconductor element 105A are electrically connected to each other. In addition, the lead 104 is fixed to the conductive pattern 103 formed in a pad shape. Next, the case material 111 is attached, and the liquid or semisolid sealing resin 108 is injected into a space surrounded by the case material 111 and then is cured by heating, thereby sealing the semiconductor element 105A and the fine metal wire 114 with the resin.

Patent Document 1: Japanese Patent Application Publication No. 2007-036014

### SUMMARY OF THE INVENTION

However, the hybrid integrated circuit device 100 mentioned above has a problem that the breakdown voltage of the insulating layer 102 is not sufficiently high in the case where a circuit (for example, a boost chopper circuit) which boosts the voltage to about several hundred volts to several thousand volts is assembled on the upper surface of the substrate 101.

Specifically, the upper surface of the substrate 101 is coated with the insulating layer 102 having a thickness of about 100 μm, and the insulating layer 102 is made of an epoxy resin into which a filler such as alumina is mixed. In other words, the conductive pattern 103 connected to the circuit elements such as the semiconductor element 105A and the substrate 101 made of a metal such as aluminum are insulated from each other with the insulating layer 102.

However, since the epoxy resin as a main material of the insulating layer 102 has a low dielectric strength, there arises a problem of a short circuit between the conductive pattern 103 and substrate 101 due to a dielectric breakdown of the insulating layer 102 when the conductive pattern 103 receives a high voltage of about several hundred volts to several thousand volts.

Moreover, if the insulating layer 102 is made thicker in order to solve the problem, the insulating layer 102 can secure the breakdown voltage, but has such a high thermal resistance that there arises another problem that the heat generated by the semiconductor element 105A during operation is poorly dissipated to the outside.

The preferred embodiment of the invention was made in view of the problems described above, and a main objective of the preferred embodiment of the invention is to provide a circuit device having both high heat dissipation property and high voltage endurance.

A circuit device in the preferred embodiment of the invention includes: a circuit board made of a metal; an island made of a metal film and provided on an upper surface of the circuit board; a fixation substrate made of a ceramic and fixed to the island with a fixing material; and an semiconductor element mounted on an upper surface of the fixation substrate.

According to the preferred embodiment of the invention, a fixation substrate made of a ceramic is placed on an upper surface of a circuit board made of a metal such as aluminum, and a semiconductor element such as a power transistor is mounted on an upper surface of the fixation substrate. Thus, the circuit board is insulated from the semiconductor element by the ceramic made of an inorganic material and having a high breakdown voltage. Accordingly, even when the semiconductor element receives a high voltage of about several thousand volts, a short circuit between the circuit board and the semiconductor element can be prevented.

### BRIEF DESCRIPTION OF THE DRAWINGS

FIG. 1 depicts views of a circuit device according to a preferred embodiment of the invention, FIG. 1A is a cross-sectional view thereof, and FIG. 1B is a cross-sectional view illustrating an enlarged portion where circuit elements are mounted.

FIG. 2 depicts views of the circuit device in the preferred embodiment of the invention, FIG. 2A is a plan view thereof, and FIG. 2B is a cross-sectional view thereof.

FIG. 3A and 3B are plan views illustrating enlarged portions of the circuit device in the preferred embodiment of the invention.

FIG. 4A is a circuit diagram illustrating a solar power generation system in which a hybrid integrated circuit device in the preferred embodiment of the invention is incorporated, and FIG. 4B is a partially enlarged circuit diagram.

FIG. 5 depicts views illustrating a manufacturing method of the circuit device in the preferred embodiment of the invention, FIG. 5A is a plan view, FIG. 5B is a cross-sectional view, and FIG. 5C is an enlarged cross-sectional view.

FIG. 6 depicts views illustrating the manufacturing method of the circuit device in the preferred embodiment of the invention, FIG. 6A is a plan view, FIG. 6B is a cross-sectional view, and FIG. 6C is an enlarged cross-sectional view.

FIG. 7 depicts views illustrating the manufacturing method of the circuit device in the preferred embodiment of the invention, and FIG. 7A to FIG. 7C are cross-sectional views.

FIG. 8 is a cross-sectional view illustrating a circuit device in the background art.

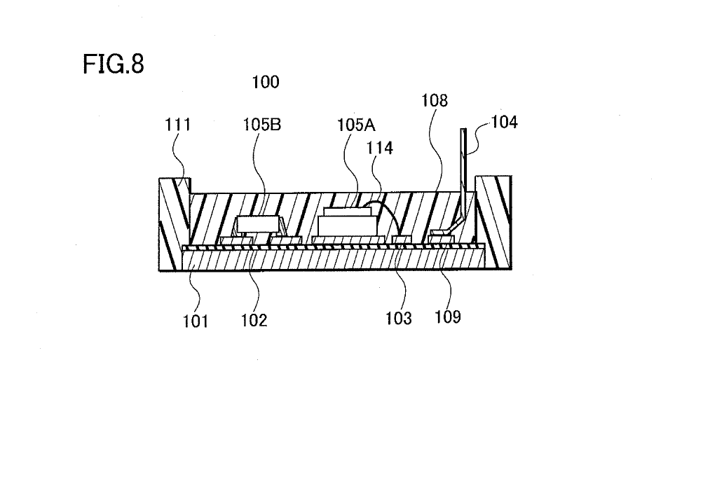

### DETAILED DESCRIPTION OF THE INVENTION

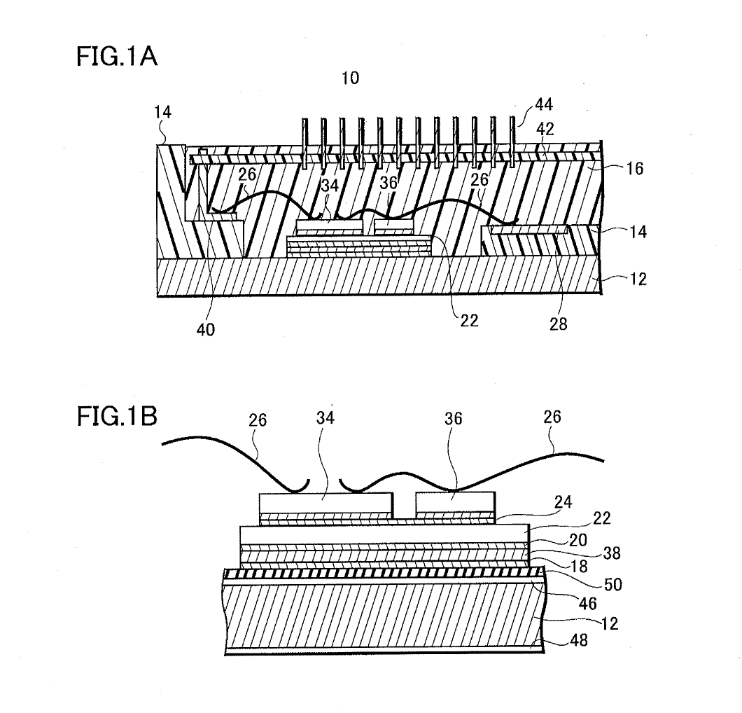

With reference to FIG. 1 to FIG. 3, the structure of a hybrid integrated circuit device 10 will be explained as an example of a circuit device. With reference to FIG. 1, the hybrid integrated circuit device 10 is a circuit device in which a hybrid integrated circuit including multiple circuit elements is assembled on an upper surface of a circuit board 12. Specifically, the hybrid integrated circuit device 10 includes ceramic substrates 22 placed on the upper surface of the circuit board 12 made of a metal, and a transistor 34 and a diode 36 (semiconductor elements) which are mounted on an upper surface of the ceramic substrate 22 (fixation substrate). In addition, a frame-shaped case material 14 is placed on the upper surface of the circuit board 12, and a sealing resin 16 is filled in a space surrounded by the case material 14. Moreover, a substrate 42 provided with signal leads 44 is disposed above the circuit board 12. Still further, an output lead 28 and the like are integrally embedded in the case material 14, and semiconductor elements including the transistor 34 are electrically connected to the output lead 28 through fine metal wires 26.

The circuit board 12 is a circuit board containing aluminum (Al), copper (Cu), or the like as a main material. When a substrate made of aluminum is employed as the circuit board 12, in order to improve the heat dissipation property, the circuit board 12 has a thickness of, for example, about 0.5 mm or more and 2.0 mm or less. Anodized films are formed on both main surfaces of the circuit board 12, and the upper surface of the circuit board 12 is coated with an insulating layer 50.

The ceramic substrate 22 is made of an inorganic solid material such as Al₂O₃ (alumina), AN (aluminum nitride), or the like, and has a thickness of, for example, 0.25 mm or more and 1.0 mm or less. The ceramic substrate 22 has a function of insulating the transistor 34 mounted on the upper surface thereof from the circuit board 12. The structure of fixing the ceramic substrate 22 to the circuit board 12 will be described later with reference to FIG. 1B. Moreover, the heat generated by the transistor 34 or the diode 36 during operation is dissipated to the outside through the ceramic substrate 22 and the circuit board 12.

The case material 14 is formed in a frame shape by injection molding of a resin material such as an epoxy resin. Moreover, the case material 14 is fixed to the upper surface of a periphery part of the circuit board 12 to form a space for resin-sealing of the circuit elements such as the transistor 34 on the upper surface of the circuit board 12.

In addition, the output lead 28 through which an output signal of a high current switched by the transistor 34 passes is integrally incorporated in the case material 14. Such a structure is implemented by injection molding of the resin material of the case material 14 with the output lead 28. In addition, wiring leads 40 each shaped in an L-character are disposed inside the case material 14, and the wiring leads 40 are connected to control electrodes of the transistors 34 through the fine metal wires 26. Here, multiple output leads 28 incorporated in the case material 14 are disposed on the same plane.

Portions of the wiring leads 40 around the upper ends are fixed by being inserted into through-holes of the substrate 42. In other words, the circuit elements such as the transistor 34 which are disposed on the upper surface of the circuit board 12 are electrically connected to the substrate 42 through the wiring leads 40. Multiple signal leads 44 are disposed on the substrate 42, and the signal leads 44 function as external connection terminals. The substrate 42 is formed of, for example, a glass epoxy substrate having a thickness of about 1 mm and having conductive patterns formed on the main surface thereof.

The sealing resin 16 is made of a resin material, such as an epoxy, into which a filler such as alumina is filled, and is filled into the space surrounded by the case material 14 on the upper surface of the circuit board 12. Further, the sealing resin 16 seals the ceramic substrate 22, the transistor 34, the diode 36, the fine metal wires 26, the substrate 42, and the like.

With reference to FIG. 1B, the structure of fixing the ceramic substrate 22 to the circuit board 12 will be explained. Firstly, when the circuit board 12 is a circuit board made of aluminum, the upper surface and the lower surface of the circuit board 12 are respectively coated with oxide films 46 and 48 formed of anodized aluminum by anodic oxidation. Further, the upper surface of the circuit board 12 is coated with the thin insulating layer 50 as mentioned above. Here, the insulating layer 50 may be omitted, and an island 18 may be formed directly on an upper surface of the oxide film 46 which coats the upper surface of the circuit board 12. This further improves the heat dissipation property.

Further, on an upper surface of the insulating layer 50 which coats the circuit board 12, the island 18 having a thickness of about 50 um is formed by etching a metal film such as copper in a predetermined shape. The island 18 is not used as wiring for an electric signal to pass. In the embodiment, the island 18 is used for improving the wettability of a fixing material 38 used to fix the ceramic substrate 22.

The lower surface of the ceramic substrate 22 is coated with a metal film 20 having a thickness of about 250 μm. Here, the metal film 20 is formed to entirely cover all over the lower surface region of the ceramic substrate 22. Thus, when solder is used as the fixing material 38, the solder is excellently welded to the entire lower surface region of the ceramic substrate 22. Moreover, the solder is excellently welded also to the island 18 provided on the upper surface of the circuit board 12. Accordingly, the ceramic substrate 22 is firmly fixed to the circuit board 12 with the fixing material 38. Further, the solder which is a metal excellent in thermal conductivity is employed as the fixing material 38 to allow the heat generated by the transistor 34 during operation to be excellently conducted to the circuit board 12.

On the upper surface of the ceramic substrate 22, a conductive pattern 24 in which a metal film having a thickness of about 250 μm is etched in a predetermined shape is formed. Further, the transistor 34 or the diode 36 is mounted on the conductive pattern 24 with the conductive fixing material such as the solder. The conductive pattern 24 is configured to include islands on which the circuit elements such as the transistor 34 are mounted, a wiring section for connecting the elements to each other, and a pad for bonding a fine metal wire, and the like.

As for the transistor 34, a MOSFET, an IGBT, or a bipolar transistor is employed. Here, as for the transistor 34, for example, a power transistor which performs switching of a high current, for example, having a current value of one ampere or more is employed. An electrode provided on the lower surface of the transistor 34 is connected to the conductive pattern 24 with the conductive fixing material such as the solder.

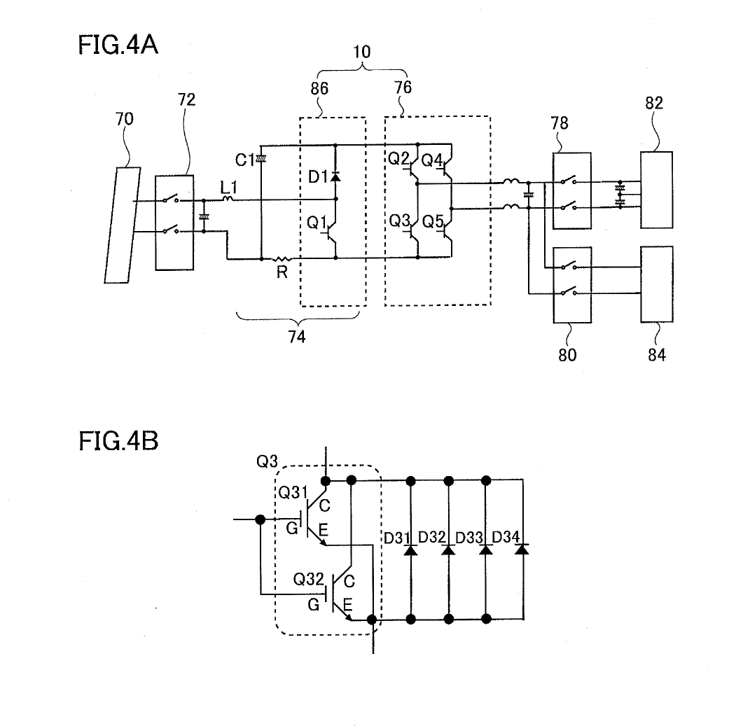

The diode 36 has an electrode provided on the upper surface thereof and connected to the transistor 34 with the fine metal wire 26, and an electrode provided on the lower surface thereof and connected to the conductive pattern 24 with the conductive fixing agent such as the solder. Here, when the transistor 34 is an IGBT, an emitter electrode provided on the upper surface of the transistor 34 is connected to an anode electrode provided on the upper surface of the diode through the fine metal wire 26. Further, a collector electrode provided on the lower surface of the transistor 34 is connected to a cathode electrode provided on the lower surface of the diode through the conductive pattern 24. The details of the connection structure will be described later with reference to the circuit diagram illustrated in FIG. 4.

Here, the fine metal wires 26 mentioned above and used for the electric connection between the transistors and the like are made of, for example, aluminum having a diameter of about 200 μm. Moreover, instead of the fine metal wires 26, ribbon bonding in which a metal foil such as aluminum is formed in a ribbon state may be employed.

In the embodiment, similar to the technology in the background art, the insulating layer 50 made of a resin is provided on the upper surface of the circuit board 12. The insulating layer 50 has a thickness of, for example, 60 μm (50 μm or more and 70 μm or less). The material of the insulating layer 50 is similar to that in the background art, and obtained such that a filler such as alumina is highly filled into a resin material such as an epoxy resin.

The upper surface of the circuit board 12 is coated with the insulating layer 50 in order to easily form the island 18. In other words, it is possible to form the island 18 made of copper directly on the upper surface of the oxide film 46 which coats the upper surface of the circuit board 12, however, this results in a weaker adhesion strength between the circuit board 12 and the island 18. Therefore, in the embodiment, the insulating layer 50 made of an organic material is interposed between the circuit board 12 and the island 18 to improve the adhesion strength between the island 18 and the circuit board 12.

Here, the breakdown voltage of the insulating layer 50 formed to be thin is lower than that in the background art. However, because the island 18 formed on the upper surface of the insulating layer 50 is not connected to the transistor 34, the high breakdown voltage is not necessary for the insulating layer 50 in the embodiment.

In addition, the thermal conductivity of the thin insulating layer 50 in the embodiment is 4 W/mK or more, which is four or more times the thermal conductivity of the thick insulating layer 102 having a thickness of about 200 μm. Accordingly, it is possible to excellently dissipate the heat generated in the transistor 34 to the outside through the insulating layer 50.

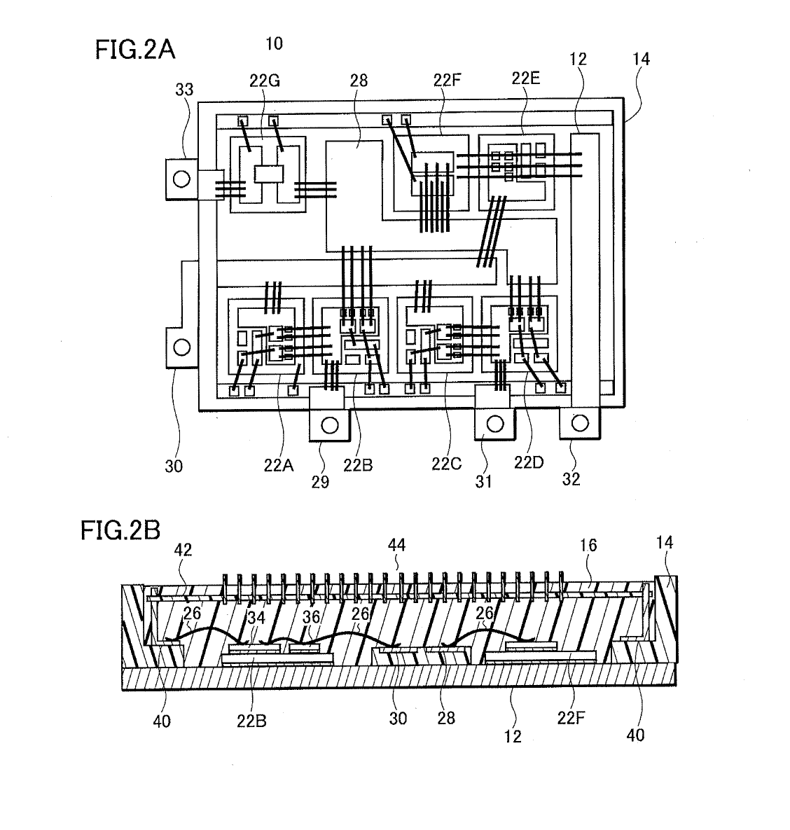

With reference to FIG. 2, the overall configuration of the hybrid integrated circuit device 10 will be explained. FIG. 2A is a plan view illustrating the hybrid integrated circuit device 10, and FIG. 2B is a cross-sectional view thereof.

With reference to FIG. 2A, multiple ceramic substrates are disposed on the upper surface of the circuit board 12. Specifically, seven ceramic substrates 22A-22G are fixed to the upper surface of the circuit board 12, and each predetermined circuit element is mounted on the upper surface of each of the ceramic substrates 22A-22G.

Transistors including an IGBT and the like and diodes are mounted on the upper surfaces of the ceramic substrates 22A to 22D. Further, transistors are mounted on the ceramic substrate 22F, diodes are mounted on the ceramic substrate 22E, and resistances are mounted on the ceramic substrate 22G. The resistance is for detecting a value of current which passes through an output lead 33.

Here, output leads integrally incorporated in the case material 14 will be explained. With reference to FIG. 2A, six output leads are incorporated here. The output lead 28 is a lead for mutually connecting the transistors inside the case material 14. The output leads 30 and 33 are leads through which direct-current power supplied from the outside passes. The output leads 29, 31, and 32 are leads for outputting alternating-current power converted by a built-in inverter circuit. In addition, a portion of each of the leads exposed to the outside may be provided with a through-hole for a screw.

Moreover, with reference to FIG. 2B, the wiring leads 40 are fixed to stepped portions provided around both right and left ends of the case material 14.

Therefore, the case material 14 of the embodiment not only has a function of securing an internal space into which the sealing resin 16 is filled, above the circuit board 12. The case material 14 of the embodiment but also has a function of fixing the output leads through which a high-voltage current passes to predetermined portions. In addition, the case material 14 of the embodiment also has a function of insulating the output leads from the circuit board 12.

As shown in FIG. 2B, the circuit elements such as transistors mounted on the upper surface of the ceramic substrates 22B and 22F are connected to the output leads 30 and 28 through the fine metal wires. In addition, electrodes provided on the upper surface of the transistor 34 are connected to the wiring leads 40 through the fine metal wires 26.

Moreover, in the hybrid integrated circuit device 10 of the embodiment, no conductive pattern is formed on the upper surface of the circuit board 12. Accordingly, the elements are electrically connected to each other via the output leads 28 and 30 embedded in the case material 14, the wiring leads 40 and the fine metal wires 26. This improves the insulation property while eliminating the high-voltage resistant insulating layer which is made of a resin and coats the upper surface of the substrate in the background art.

Moreover, although the output leads 28 and 30 are insulated from the circuit board 12 with the case material 14, the case material 14 which coats the lower surfaces of the output leads 28 and 30 is thick with a thickness of about 1.0 mm or more, whereby a sufficient voltage endurance can be obtained.

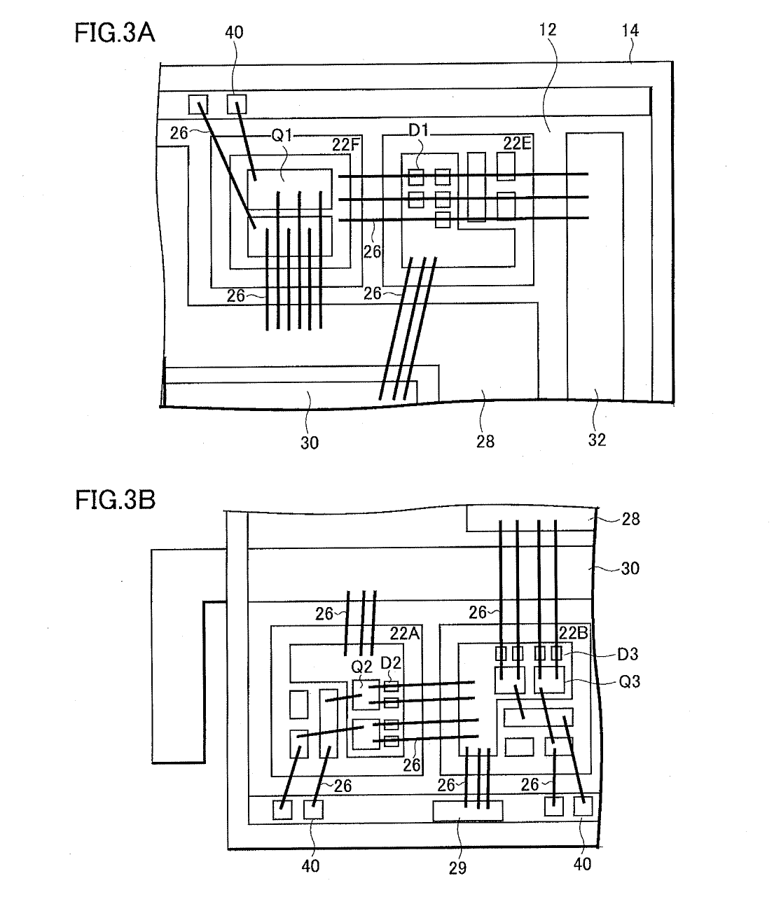

With reference to FIG. 3, the structure of connecting the circuit elements placed on the upper surfaces of the respective ceramic substrates will be explained. FIG. 3A and FIG. 3B are plan views illustrating partial enlarged portions of the circuit board 12. Note that, in the drawings, hatched regions indicate conductive patterns formed on the upper surfaces of the ceramic substrates.

With reference to FIG. 3A, on the upper surface of the circuit board 12, the ceramic substrates 22F and 22E are adjacent to but separated from each other by a predetermined distance. Here, elements mounted on the ceramic substrates 22F and 22E constitute a converter circuit illustrated in FIG. 4A.

Two transistors Q1s are fixed to the conductive pattern disposed on the upper surface of the ceramic substrate 22F via a conductive jointing material such as the solder. Here, as for the transistor Q1, an IGBT or a MOSFET is employed. Further, collector electrodes on the lower surfaces of the transistors are connected through the conductive pattern formed on the upper surface of the ceramic substrate 22F. Moreover, emitter electrodes formed on the upper surfaces of the two transistors Q1s are connected to the output lead 28 through the multiple fine metal wires 26. In addition, gate electrodes provided on the upper surfaces of the transistors Q1s are connected to the wiring leads 40 embedded in the case material 14 through the fine metal wires 26.

Multiple diodes D1s are mounted on the conductive pattern formed on the upper surface of the ceramic substrate 22E via the conductive jointing material such as the solder. Anode electrodes formed on the upper surfaces of the diodes D1s are connected to the collector electrodes of the transistors Q1s through the fine metal wires 26 and the conductive pattern of the ceramic substrate 22F. Further, cathode electrodes formed on the lower surfaces of the diodes D1s are connected to the conductive pattern of the ceramic substrate 22E through the output lead 30 and the fine metal wires 26.

With reference to FIG. 3B, transistors and diodes constituting an inverter are mounted on the upper surfaces of the ceramic substrates 22A and 22B.

Specifically, on the upper surface of the ceramic substrate 22A, two transistors Q2s and four diodes D2s are connected to the same conductive pattern via the solder. Accordingly, collector electrodes provided on the lower surfaces of the transistors Q2s are electrically connected to cathode electrodes provided on the lower surfaces of the diodes D3s. Moreover, gate electrodes disposed on the upper surfaces of the transistors Q2s connected to the wiring leads 40 of the case material 14 through the conductive patterns of the ceramic substrate 22A and the fine metal wires 26. Meanwhile, emitter electrodes disposed on the upper surfaces of the transistors Q2s are connected to anode electrodes provided on the upper surfaces of the diodes D3s through the fine metal wires 26, and is further connected to the conductive pattern of the ceramic substrate 22B. Accordingly, the electrodes provided on the upper surfaces of the transistors Q2s and the diodes D3s mounted on the ceramic substrate 22A are connected to electrodes provided on the lower surfaces of transistors Q3s and diodes D3s mounted on the adjacent ceramic substrate 22B.

Here, the upper surface of the ceramic substrate 22A is provided with a pattern for element mounting and multiple patterns for connecting fine metal wires to each other. Further, the same conductive patterns are formed on the ceramic substrates 22A-22D on which elements constituting an inverter circuit are mounted. Moreover, although the ceramic substrate 22E is not a substrate on which the elements of the inverter are mounted, a ceramic pattern having the same conductive pattern as those of the ceramic substrates 22A-22D is employed. Therefore, providing the common pattern shape to the ceramic substrates reduces the kinds of pattern shapes of the ceramic substrates, thereby making it possible to reduce the manufacturing cost.

The configuration of conductive patterns provided to the ceramic substrate 22B and elements mounted thereon are similar to those of the ceramic substrate 22A. In other words, rear surface electrodes of the two transistors Q3s and the four the diodes D3s are connected to the upper surface of one conductive pattern via the solder, and emitter electrodes of the transistors Q3s and anode electrodes of the diodes D3s are connected to the output lead 28 through the fine metal wires 26. In addition, gate electrodes which are control electrodes of the transistors Q3s are connected to the wiring leads 40 through the conductive patterns on the ceramic substrate 22B and the fine metal wires. Moreover, the conductive pattern on which the transistors Q3s and the like are mounted is connected to the output lead 29 through the multiple fine metal wires 26.

Moreover, the pattern shape of the ceramic substrates 22C and 22D, elements mounted on the ceramic substrates 22C and 22D, and the connection structure thereof, illustrated in FIG. 2A, are similar to those of the ceramic substrates 22A and 22B mentioned above. In other words, two transistors and four diodes are connected to each of the upper surfaces of the ceramic substrates 22C and 22D. Further, the elements placed on the upper surface of the ceramic substrate 22C are connected to the elements placed on the ceramic substrate 22D through the fine metal wires. In addition, the elements mounted on each of the upper surfaces of the ceramic substrates 22C and 22D are electrically connected to the output leads and the wiring leads through the fine metal wires.

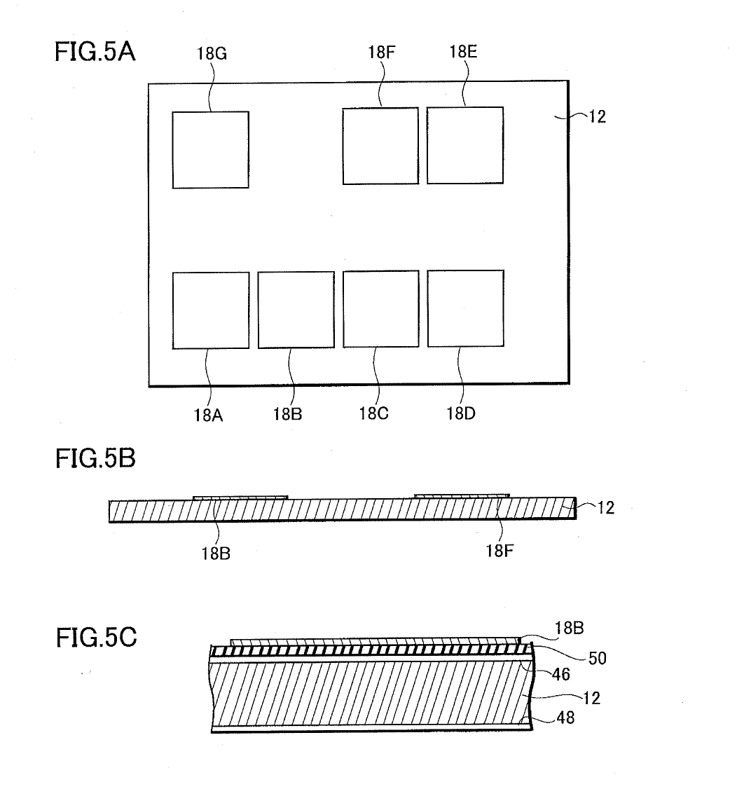

Next, with reference to FIG. 4, the circuit configuration of a solar cell generation system in which the hybrid integrated circuit device 10 mentioned above is incorporated will be explained. FIG. 4A is a circuit diagram illustrating an overall solar cell generation system, and FIG. 5B is a circuit diagram illustrating the transistor Q3 included in the system in detail.

The generation system illustrated in the drawing is provided with a solar cell 70, a solar cell opening and closing unit 72, a boost chopper 74, an inverter 76, and relays 78 and 80. The electric power generated by the generation device of such a configuration is supplied to an electric power system 82 or a load 84 for self-sustaining operation. Moreover, a converter 86 and the inverter 76 which are parts of the boost chopper 74 are incorporated in the hybrid integrated circuit device 10 of the embodiment.

The solar cell 70 is a converter to convert radiated light into electric power to be outputted, and outputs the direct-current electric power. Although one solar cell 70 is illustrated here, multiple solar cells 70 connected in series may be employed.

The solar cell opening and closing unit 72 is provided with a function of collecting the electricity generated in the solar cell 70 and preventing backflow thereof, and supplying a direct-current current to the boost chopper 74.

The boost chopper 74 is provided with a function of boosting a voltage of the direct-current power supplied from the solar cell 70. In the boost chopper 74, the transistor Q1, which is a MOSFET, repeats an ON operation and an OFF operation periodically to boost the direct-current power at the voltage of about 250 V generated by the solar cell 70 to the direct-current power of about 370 V. Specifically, the boost chopper 74 is provided with a coil L1 connected in series to an output terminal of the solar cell, and the transistor Q1 connected between the coil L1 and a ground terminal. Further, the direct-current power boosted by the coil L1 is supplied to the inverter 76 of the next stage via the diode D1 and a smoothing capacitor C1 for a backflow device.

In the embodiment, the transistors Q1s and the diodes D1s included in the boost chopper 74 are placed on the upper surfaces of the ceramic substrates 22F and 22E illustrated in FIG. 2A. Moreover, the switching of the transistor Q1 is performed on the basis of control signals externally supplied through the signal leads 44 and the wiring leads 40, illustrated in FIG. 1A.

The direct-current power boosted by the boost chopper 74 is converted into alternating-current power having a predetermined frequency by the inverter 76. The inverter 76 is provided with the two transistors Q2 and Q4 connected in series between the output terminal of the boost chopper 74, and two transistors Q3 and Q5 connected in series as well. Moreover, the switching of these transistors are controlled by a control signal supplied from the outside, the transistors Q2 and Q3 and the transistors Q4 and Q5 are complementarily switched. Further, the alternating-current power set to the predetermined frequency by these switching is outputted to the outside from a connection point between the transistors Q2 and Q3 and a connection point between the transistors Q4 and Q5. Here, the two-phase inverter circuit consisting of four transistors is constructed.

In the embodiment, the transistors Q2 to Q5 constituting the inverter 76 are fixed to the ceramic substrates 22A, 22B, 22C, and 22D illustrated in FIG. 2A.

The alternating-current power converted by the inverter 76 is supplied to the commercial electric power system 82 or the load 84 for self-sustaining operation. The relay 78 is interposed between the electric power system 82 and the inverter 76, the relay 78 is in a conduction state at the normal time, and the relay 78 is in a cut-off state if abnormality is detected either one of electric power system 82 and the inverter 76. Moreover, the relay 80 is interposed also between the inverter 76 and the load for self-sustaining operation, and the supply of electric power is cut off by the relay 80 in an abnormal state.

As mentioned above, in the embodiment, the elements included in the boost chopper 74 and the inverter 76 are fixed to the upper surfaces of the ceramic substrates 22 illustrated in FIG. 1. Accordingly, when the elements receive the voltage at several hundred volts to several thousand volts without a high-breakdown voltage insulating resin material being interposed between these elements and the circuit board 12, no short circuit is generated between the elements and the circuit board 12.

With reference to FIG. 4B, the transistor Q3 which is one of the transistors included in the inverter 76 mentioned above is configured to include transistors Q31 and Q32, which are two IBGTs, and four diodes D31, D32, D33, and D34 which are inversely connected to main electrodes of these transistors.

The transistor Q31 and the transistor Q32 are connected to each other in parallel. Specifically, gate electrodes, emitter electrodes, and collector electrodes of the transistor Q31 and the transistor Q32 are connected in common. Thus, the larger current capacity can be obtained than in the case of one transistor.

Moreover, anode electrodes of the diodes D31, D32, D33, and D34 are connected to the emitter electrodes of the transistor Q31 and the transistor Q32. Further, cathode electrodes of these diodes are connected to the collector electrodes of the transistor Q31 and the transistor Q32.

Next, with reference to FIG. 5 to FIG. 7, a manufacturing method of the hybrid integrated circuit device 10 mentioned above will be explained.

Firstly, with reference to FIG. 5, the circuit board 12 is prepared. FIG. 5A is a plan view illustrating this process, and FIG. 5B and FIG. 5C are cross-sectional views illustrating this process.

With reference to FIG. 5A and FIG. 5B, the circuit board 12 to be prepared is a circuit board made of a thick metal, such as aluminum and copper, having a thickness of about 1 mm to 3 mm. When aluminum is employed as a material of the circuit board 12, the upper surface and the lower surface of the circuit board 12 are coated with anodized films. In addition, the upper surface of the circuit board 12 is coated with the insulating layer 50 having a thickness of about 60 μm or less. This allows an adhesion strength of an island 18B and the like to the circuit board 12 to be improved.

Note that, the circuit board 12 is molded in a predetermined shape by performing press processing or grinding processing with respect to a large-sized circuit board.

Islands 18A-18G are formed by etching the copper foil stuck on the upper surface of the circuit board 12 in a predetermined shape. The islands 18A-18G are not for circuit elements such as transistors being mounted thereon but for improving the wettability of solder used when ceramic substrate is mounted, which is described later.

With reference to FIG. 5C, when aluminum is employed as a material of the circuit board 12, the upper surface and the lower surface of the circuit board 12 are respectively coated with the oxide films 46 and 48 formed of anodized aluminum by anodic oxidation. In addition, the upper surface of the oxide film 46 is coated with the insulating layer 50 made of a resin material, and on the upper surface of the insulating layer 50, the island 18B is formed.

Further, the island 18B is formed on the upper surface of the insulating layer 50 which coats the upper surface of the circuit board 12. Accordingly, although the insulating layer 50 is present between the circuit board 12 and the island 18B, because the insulating layer 50 formed to be thin has an extremely high thermal conductivity, therefore the thermal conductivity of the entire substrate is extremely high.

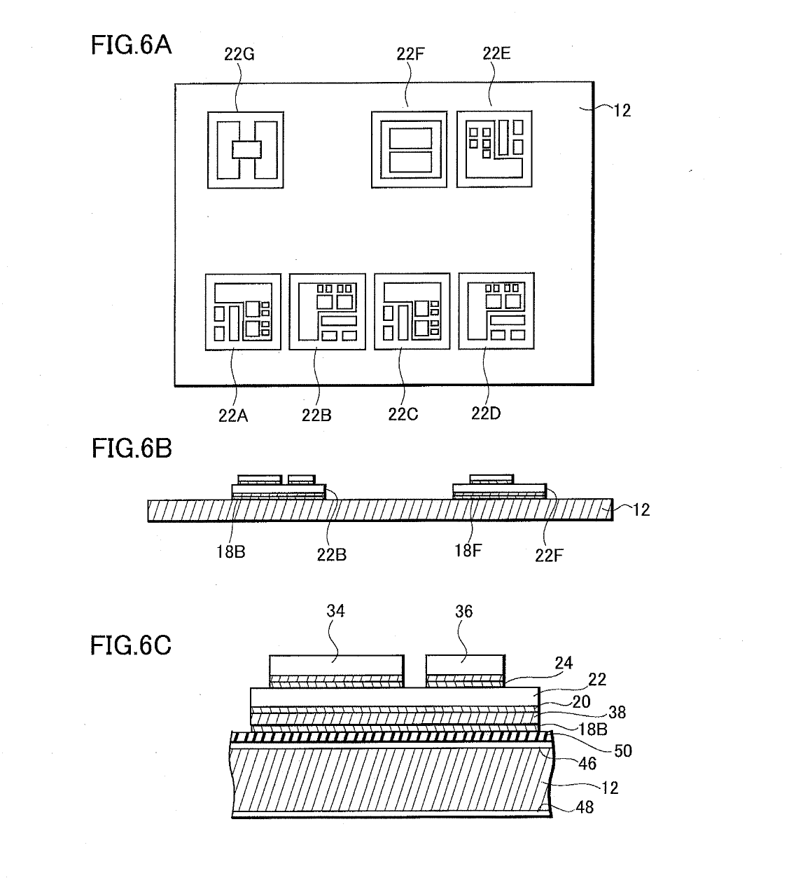

Next, with reference to FIG. 6, ceramic substrates are disposed on predetermined portions of the circuit board 12. FIG. 6A is a plan view illustrating this process, and FIG. 6B and FIG. 6C are cross-sectional views.

With reference to FIG. 6A, the ceramic substrates 22A-22G on which predetermined circuit elements such as transistors and diodes are mounted are fixed to the upper surface of the circuit board 12. Here, the ceramic substrates 22A-22G are respectively fixed to the upper surfaces of the islands 18A-18G formed on the upper surface of the circuit board 12 in the previous process.

With reference to FIG. 6C, the conductive pattern 24 and the metal film 20 are respectively formed on the upper surface and the lower surface of the ceramic substrate 22.

Further, the metal film 20 with which the lower surface of the ceramic substrate 22 is coated is fixed to the island 18 provided on the upper surface of the circuit board 12 with the fixing material 38 such as solder. The metal film 20 is provided to entirely cover all over the lower surface of the ceramic substrate 22, and thereby the fixing material 38 is strongly adhered on the entire lower surface region of the ceramic substrate 22. Accordingly, the ceramic substrate 22 is firmly joined to the circuit board 12.

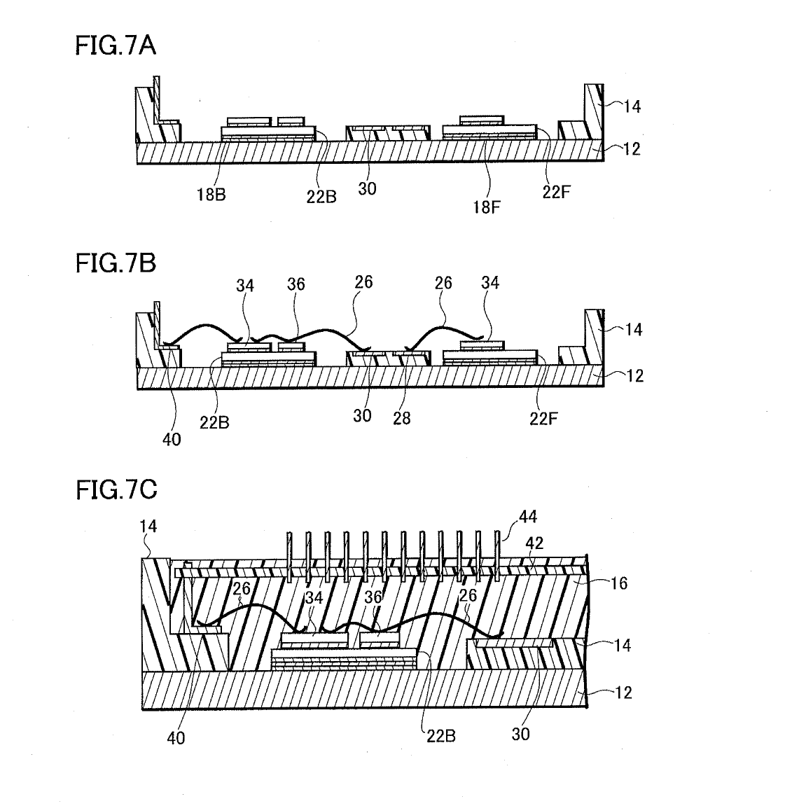

Next, with reference to FIG. 7A, the case material 14 is bonded to the upper surface periphery part of the circuit board 12. In the case material 14, as mentioned above, the output leads and the wiring leads are incorporated in advance. The case material 14 is bonded to the upper surface of the circuit board 12 with a bonding material such as an epoxy resin.

Next, with reference to FIG. 7B, the circuit elements and the leads are electrically connected to each other by the fine metal wires 26. Specifically, the gate electrode of the transistor 34 fixed to the upper surface of the ceramic substrate 22B is connected to the wiring lead 40 through the fine metal wire 26. Moreover, the emitter electrode disposed on the upper surface of the transistor 34, together with the anode electrode provided on the upper surface of the diode 36, are connected to the output lead 30. Moreover, the transistor 34 mounted on the upper surface of the ceramic substrate 22F is connected to the output lead 28 through the fine metal wires 26.

In this process, the fine metal wires made of aluminum having a diameter of about 200 μm are used for connection of the circuit elements. Moreover, instead of the wire bonding by the fine metal wires, ribbon bonding in which a ribbon-shaped aluminum foil is used may be employed.

Next, with reference to FIG. 7C, upper end portions of the wiring leads 40 are inserted into holes of the substrate 42. Accordingly, the wiring leads 40 are connected to the signal leads 44 provided to the substrate 42 through the conductive pattern formed on the surface of the substrate 42.

In addition, the sealing resin 16 is filled into a space surrounded by the case material 14. As for the sealing resin 16, a silicon resin or an epoxy resin is employed. Moreover, a resin material into which a filler such as alumina is filled may be employed as the sealing resin 16. The transistor 34, the diode 36, the fine metal wires 26, the wiring leads 40, the substrate 42, and the like are resin-sealed by the sealing resin 16.

The hybrid integrated circuit device 10 illustrated in FIG. 1 is manufactured through the processes above.

1. A circuit device, comprising:
a circuit board made of a metal;
an island made of a metal film and provided on an upper surface of the circuit board;
a fixation substrate made of a ceramic and fixed to the island with a fixing material; and
a semiconductor element mounted on an upper surface of the fixation substrate.

2. The circuit device according to claim 1, wherein
a metal film is provided on a lower surface of the fixation substrate, and
the fixing material is in contact with the island provided on the upper surface of the circuit board and the metal film provided on the lower surface of the fixation substrate.

3. The circuit device according to claim 1, wherein
the upper surface of the circuit board is coated with an insulating layer made of a resin material, and
the island is formed on an upper surface of the insulating layer.

4. The circuit device according to claim 1, wherein
a plurality of the fixation substrates are placed on the upper surface of the circuit board, and
a transistor and a diode connected to a main electrode of the transistor are mounted on the upper surfaces of the fixation substrates.

5. The circuit device according to claim 1, further comprising:
a case material abutting on a periphery part of the circuit board; and
a plurality of leads incorporated into the case material, one end of each lead being exposed in an internal space of the case material, and the other end thereof being disposed outward of the case material, wherein
an electrode of the semiconductor element is connected to any of the leads exposed in the internal space of the case material.

6. The circuit device according to claim 5, wherein the plurality of leads are disposed on the same plane.

7. The circuit device according to claim 5, further comprising a sealing resin filled in the internal space of the case material, and coating the semiconductor element.

8. The circuit device according to claim 1, wherein
a converter circuit configured to boost direct-current power inputted from the outside and an inverter circuit configured to convert the boosted direct-current power into alternating-current power are assembled on the upper surface of the circuit board, and
the semiconductor element constitutes the converter or the inverter.
